(19) United States
(12) Patent Application Publication
(10) Pub. No.: US 2026/0066561 A1
(43) Pub. Date: Mar. 5, 2026

(54) SYSTEMS AND METHODS FOR ADDING INSERT ASSEMBLY TO AN INFORMATION HANDLING RESOURCE MODULE

(71) Applicant: Dell Products L.P., Round Rock, TX (US)

(72) Inventors: Megan Cherie WINGFIELD, Dalzell, SC (US); Emily CLARK, Round Rock, TX (US); Timothy SHEDD, Lithia, FL (US)

(73) Assignee: Dell Products L.P., Round Rock, TX (US)

(21) Appl. No.: 18/816,935

(22) Filed: Aug. 27, 2024

(51) Int. Cl. H01R 12/72; H01R 12/70; H05K 1/18

(52) U.S. Cl. CPC H01R 12/721; H01R 12/7058; H01R 12/7064; H01R 12/725; H05K 1/181; H05K 2201/10159

(57) ABSTRACT

An information handling system may include an information handling resource comprising a circuit board and an insert assembly mechanically coupled to the information handling resource and comprising a base mechanically attached via a press-fit mechanical coupling to an edge of the circuit board and a body mechanically coupled to the base.

### TECHNICAL FIELD

The present disclosure relates in general to information handling systems, and more particularly to adding an insert assembly to an information handling resource module in an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often use one or more circuit boards. A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

A type of circuit board often used in information handling systems is memory modules, such as dual-inline memory modules (DIMMs). DIMMs typically comprise a circuit board with a plurality of memory chips mounted thereon.

In modern information handling systems, it is also often important to thermally control temperatures within an information handling system, to ensure information handling resources operate within optimal temperatures. Accordingly, information handling systems often include thermal control systems configured to regulate temperatures within information handling systems. Such thermal control systems often employ one or more air movers (e.g., fans or blowers) configured to drive air over information handling resources for cooling. In addition or alternatively, such thermal control systems may include a liquid cooling system, which may convey a flow of chilled liquid proximate to information handling resources for cooling.

Liquid cooling can be both expensive and difficult to implement for all information handling resources within an information handling system. Accordingly, systems and methods for improving air mover-based cooling are often desired. For example, it has been shown that insertion of a spiraling “twisted tape” geometry, similar to those used in nuclear cooling tubes, between adjacent DIMMs improves thermal performance in an information handling system, including within such DIMMs. However, insertion of items between DIMMs may run the risk of shearing off or otherwise damaging memory chips and/or other components mounted to circuit boards of the DIMMs. Further, DIMM banks are not always fully populated, and those that are may include DIMM blanks, which may not have the same geometry as DIMMs themselves. Thus, any solution that uses such inserts must accommodate any configuration of DIMMs and blanks within an information handling system, and must be usable with multiple DIMM pitches and bank sizes.

### SUMMARY

In accordance with the teachings of the present disclosure, the disadvantages and problems associated with adding inserts to an information handling resource may be reduced or eliminated.

In accordance with embodiments of the present disclosure, an information handling system may include an information handling resource comprising a circuit board and an insert assembly mechanically coupled to the information handling resource and comprising a base mechanically attached via a press-fit mechanical coupling to an edge of the circuit board and a body mechanically coupled to the base.

In accordance with these and other embodiments of the present disclosure, an insert assembly may be configured to mechanically couple to a circuit board of an information handling resource, the insert assembly comprising a base configured to mechanically attach via a press-fit mechanical coupling to an edge of the circuit board and a body mechanically coupled to the base.

In accordance with these and other embodiments of the present disclosure, a method for constructing an insert assembly configured to mechanically couple to a circuit board of an information handling resource may include mechanically coupling a body to a base such that the base, wherein the base is configured to mechanically attach via a press-fit mechanical coupling to an edge of the circuit board.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2A illustrates an isometric perspective view of a memory module and an insert assembly prior to mechanical attachment of the insert assembly to the memory module, in accordance with embodiments of the present disclosure;

FIG. 2B illustrates an isometric perspective view of an insert assembly mechanically attached to a memory module with a body of the insert assembly in an open position, in accordance with embodiments of the present disclosure;

FIG. 2C illustrates an isometric perspective view of an insert assembly mechanically attached to a memory module with a body of the insert assembly in a closed position, in accordance with embodiments of the present disclosure;

FIG. 2D illustrates a front elevation view of an insert assembly mechanically attached to a memory module with a body of the insert assembly in a closed position, in accordance with embodiments of the present disclosure;

FIG. 3A illustrates a side cross-sectional elevation view of an insert assembly mechanically attached to a memory module with a body of the insert assembly in an open position, in accordance with embodiments of the present disclosure;

FIG. 3B illustrates a side cross-sectional elevation view of an insert assembly mechanically attached to a memory module with a body of the insert assembly in a closed position, in accordance with embodiments of the present disclosure;

FIG. 3C illustrates a side cross-sectional elevation view of an insert assembly with a body of the insert assembly in a closed position, in accordance with embodiments of the present disclosure; and

FIGS. 4A and 4B (which may be referred to herein collectively as “FIG. 4”) illustrate a side cross-sectional elevation view of an insert assembly mechanically attached to a memory module with a body of the insert assembly in a closed position and the memory module installed into a slot, in accordance with embodiments of the present disclosure.

### DETAILED DESCRIPTION

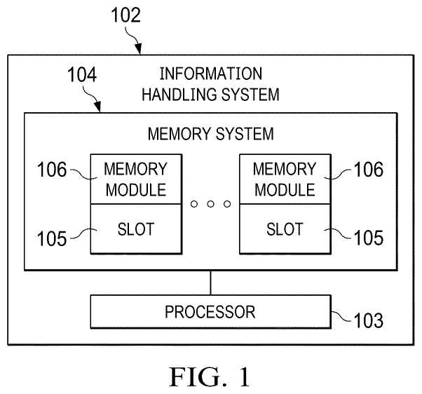

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may be a personal computer. In some embodiments, information handling system 102 may comprise or be an integral part of a server. In other embodiments, information handling system 102 may be a portable information handling system (e.g., a laptop, notebook, tablet, handheld, smart phone, personal digital assistant, etc.). As depicted in FIG. 1, information handling system 102 may include a processor 103 and a memory system 104 communicatively coupled to processor 103.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory system 104 and/or another component of information handling system 102.

Memory system 104 may be communicatively coupled to processor 103 and may include any system, device, or apparatus configured to retain program instructions and/or data for a period of time (e.g., computer-readable media). Memory system 104 may include RAM, EEPROM, a PCMCIA card, flash memory, magnetic storage, opto-magnetic storage, or any suitable selection and/or array of volatile or non-volatile memory that retains data after power to information handling system 102 is turned off.

As shown in FIG. 1, memory system 104 may comprise a plurality of memory slots 105, each configured to receive a corresponding memory module 106. A memory slot 105 may include any system, device, or apparatus configured to receive a memory module 106 in order to electrically couple such memory module 106 to processor 103. Each memory module 106 may include any system, device or apparatus configured to retain program instructions and/or data for a period of time (e.g., computer-readable media). Each memory module 106 may include a dynamic random access memory (DRAM) module (e.g, a dual in-line package (DIP) memory, a Single In-line Pin Package (SIPP) memory, a Single-Inline Memory Module (SIMM), a Dual-Inline Memory Module (DIMM), a Ball Grid Array (BGA)), or any other suitable memory.

In addition to processor 103 and memory system 104, information handling system 102 may include one or more other information handling resources.

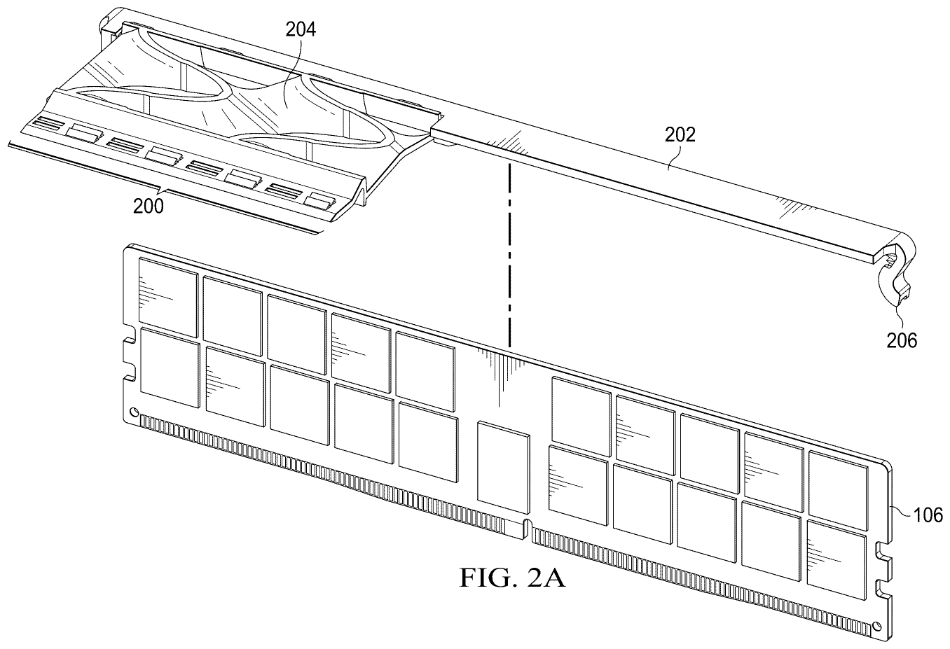

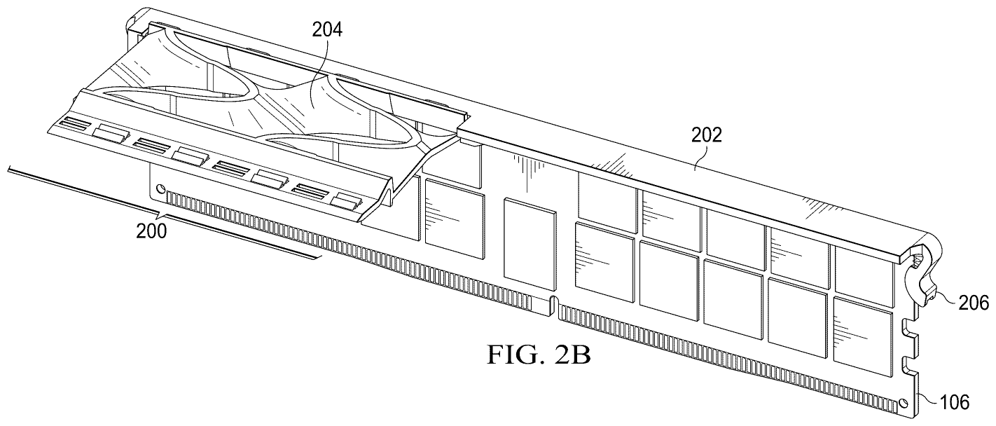

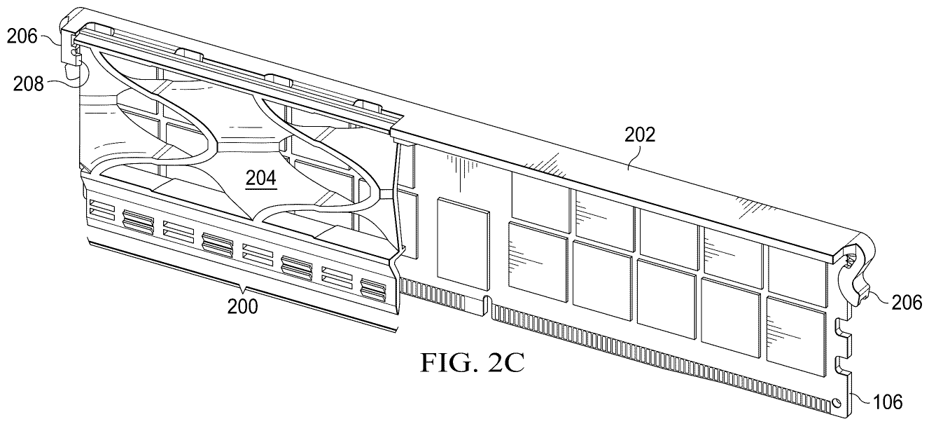

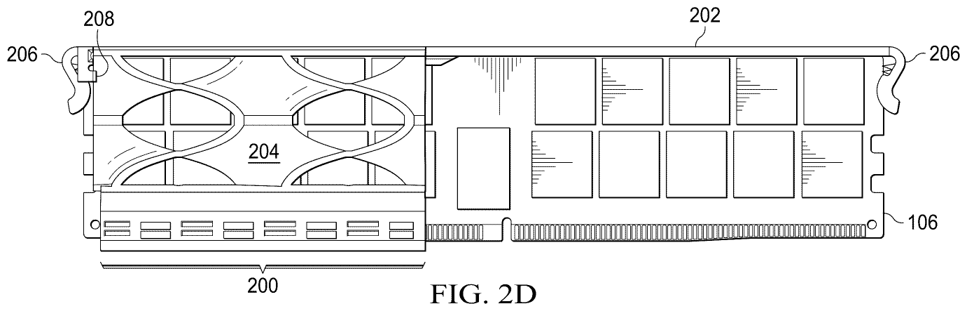

FIG. 2A illustrates an isometric perspective view of a memory module 106 and an insert assembly 200 prior to mechanical attachment of insert assembly 200 to memory module 106, in accordance with embodiments of the present disclosure. As shown in FIG. 2A, insert assembly 200 may include a base 202 and a body 204 rotatably coupled to base 202 via an axis that is substantially parallel with a length (e.g., the longest physical dimension) of base 202. Such rotatable coupling may be achieved in any manner known to rotatably couple one mechanical member to another.

As described in greater detail below, base 202 may comprise one or more mechanical features configured to mechanically press fit base 202 to a top edge (e.g., an edge opposite a bottom edge comprising an electrical edge connector) of memory module 106. Body 204 may include any mechanical member of any suitable geometry, including a “swirling” or “helical” geometry such as that shown in FIG. 2A that may cause air flowing through body 204 to move in a desired way, particularly when body 204 is proximate to one or two memory modules 106. However, any suitable geometry of any suitable dimension may be formed or otherwise present in body 204, or any suitable body that may enhance heat transfer may be used to implement body 204.

To mechanically attach insert assembly 200 to memory module 106, a person (e.g., a user or technician of information handling system 102) may, prior to installing memory module 106 into a slot 105, and with body 204 in an open position relative to base 202 as shown in FIG. 2A, align press fit features of base 202 with the top edge of memory module 106 and press down upon base 202, causing base 202 to mechanically press fit to memory module 106, as shown in FIG. 2B, which depicts an isometric perspective view of insert assembly 200 mechanically attached to memory module 106 with body 204 of insert assembly 200 in the open position relative to base 202, in accordance with embodiments of the present disclosure.

After base 202 is press fit to memory module 106, the person may then apply a force to body 204 to cause body 204 to rotate relative to base 202 from the open position shown in FIG. 2B to the closed position shown in FIG. 2C, which depicts an isometric perspective view of insert assembly 200 mechanically attached to memory module 106 with body 204 of insert assembly 200 in the closed position relative to base 202, in accordance with embodiments of the present disclosure. For further illustration, FIG. 2D illustrates a front elevation view of insert assembly 200 mechanically attached to memory module 106 with body 204 in the closed position relative to base 202, in accordance with embodiments of the present disclosure,

[symbol]

By rotating body 204 from the open position to the closed position after mechanical attachment of base 202 to memory module 106, the likelihood of shearing off or otherwise damaging memory chips or other components of memory module 106 during installation of insert assembly 200 may be reduced or eliminated as compared to existing approaches. Once insert assembly 200 has been mechanically attached to memory module 106 and body 204 is in the closed position relative to base 202, memory module 106 may be installed into slot 105 with insert assembly 200 attached.

Base 202 may include one or more mechanical features to ensure press fitting of base 202 to memory module 106. For example, as shown in FIGS. 2A-2D, base 202 may comprise one or more tensioning features 206 configured to have mechanical tension relative to the remainder of base 202 such that when base 202 is mechanically attached to memory module 106, tensioning features 206 apply a mechanical force to the side edges and/or the surfaces of memory module 106 to further mechanically retain base 202 to memory module 106, in the absence of an applied countervailing force that overcomes the mechanical force.

Further, base 202 may include one or more mechanical features to retain body 204 in the closed position relative to base 202. For example, as shown in FIGS. 2C and 2D, base 202 may include a retention feature 208 (which may be proximate to tensioning features 206, if present) extending therefrom to retain body 204 in the closed position in the absence of an applied countervailing force that overcomes any force applied by retention feature 208 to maintain body 204 in the closed position.

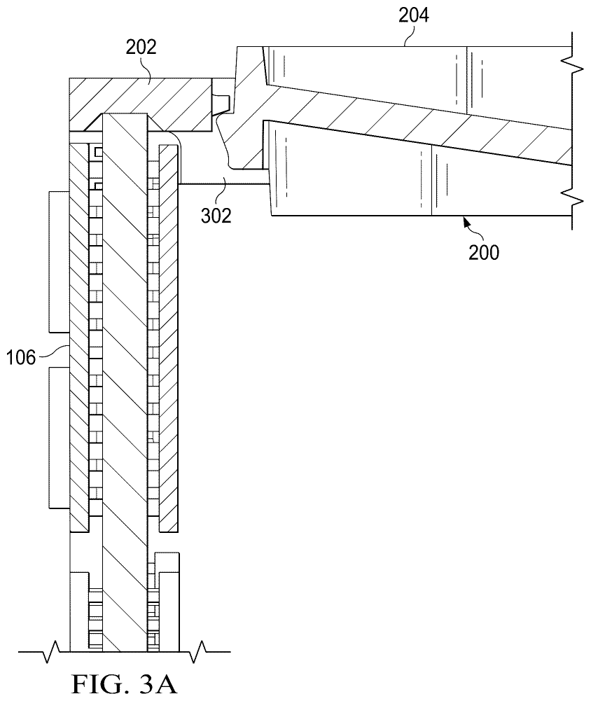

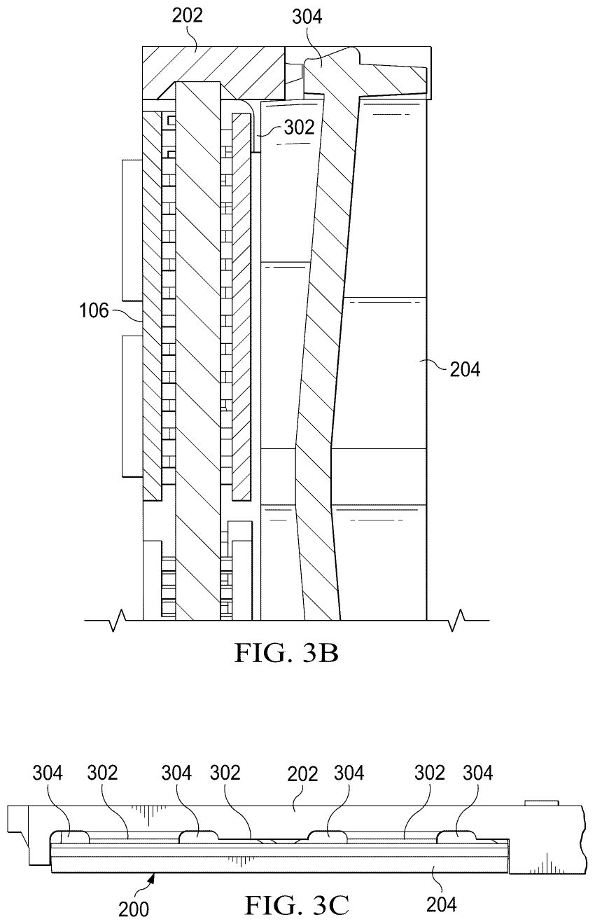

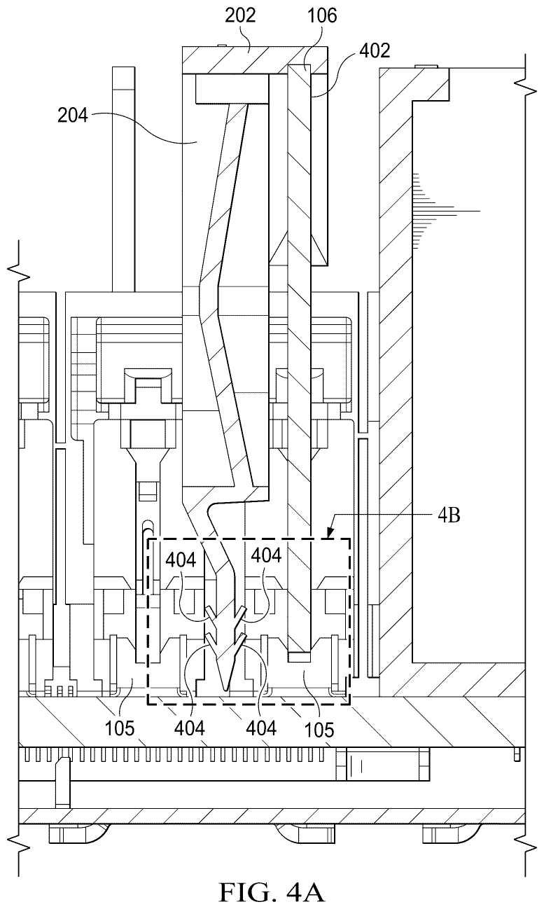

FIG. 3A illustrates a side cross-sectional elevation view of insert assembly 200 mechanically attached to memory module 106 with body 204 in the open position relative to base 202, in accordance with embodiments of the present disclosure. FIG. 3B illustrates a side cross-sectional elevation view of insert assembly 200 mechanically attached to memory module 106 with body 204 in the closed position relative to base 202, in accordance with embodiments of the present disclosure. FIG. 3C illustrates a side cross-sectional elevation view of insert assembly 200 with body 204 in the closed position relative to base 202, in accordance with embodiments of the present disclosure. As shown in FIGS. 3A-3C, in addition to or in lieu of retention feature 208, base 202 may include one or more fingers 302 configured (e.g., sized and/or shaped) to mechanically engage with corresponding features 304 in order to bias body 204 in the open position relative to base 202 (e.g., to keep body 204 in the open position while a person is mechanically attaching base 202 to memory module 106) and/or to bias body 204 in the closed position relative to base 202 (e.g., to keep body 204 in the closed position while a person is installing memory module 106 into a slot 105 and/or while memory module 106 is installed in a slot 105). Fingers 302 and/or features 304 may be configured (e.g., sized or sized) to render it easy or difficult for a person to pivot body 204 about base 202.

Although the foregoing contemplates body 204 being rotatably coupled to base 202, in some embodiments, body 204 may be configured to mechanically coupled to base 202 in a manner other than rotationally. For example, in some embodiments, base 202 and body 204 may include features such that body 204 may “clip” to base 202.

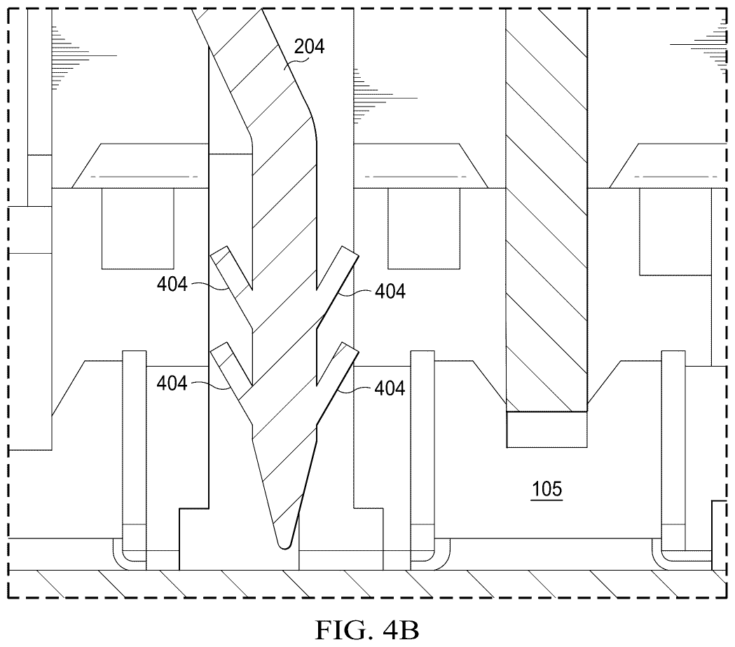

FIG. 4 illustrates a side cross-sectional elevation view of insert assembly 200 mechanically attached to memory module 105 with body 204 in the closed position relative to base 202 and memory module 106 installed into a slot 105, in accordance with embodiments of the present disclosure.

FIG. 4 depicts a recess 402 that may be formed in base 202 wherein recess 402 may engage with the top edge or memory module 106 to mechanically attach base 202 to memory module 106. Further, FIG. 4 shows that body 204 may include alignment features 404 extending therefrom. Alignment features 404 may assist in alignment between body 204 and adjacent memory modules 106 and/or minimize shock and vibration. Although FIG. 4 depicts alignment features 404 as “barbs,” any other suitable mechanical feature may be used to implement alignment features 404.

Although the foregoing describes mounting a mechanical accessory (e.g., insert assembly 200) in near proximity to memory modules 106 in an information handling system, it is understood that the methods and systems described herein may be applied for mounting such mechanical accessory to any suitable information handling resource other than a memory module.

While the terms “top” and “bottom” are used for purposes of exposition and clarity, such terms are not intended to limit any of the mounts disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S. C. § 112(f) unless the words “means for” or “step for” are explicitly used in the particular claim.

What is claimed is:

1. An information handling system comprising:
an information handling resource comprising a circuit board; and
an insert assembly mechanically coupled to the information handling resource and comprising:
a base mechanically attached via a press-fit mechanical coupling to an edge of the circuit board; and
a body mechanically coupled to the base.

2. The information handling system of claim 1, wherein the base comprises at least one tensioning feature configured to have mechanical tension relative to the remainder of the base such that when the base is mechanically attached to the circuit board, the at least one tensioning feature is configured to apply a mechanical force to the circuit board to mechanically retain the base to the circuit board.

3. The information handling system of claim 1, wherein the body is rotatably coupled to the base and configured to rotate relative to the base between an open position and a closed position.

4. The information handling system of claim 3, wherein the base comprises at least one mechanical feature configured to mechanically engage with a corresponding mechanical feature of the body in order to bias the body in the open position relative to the base and/or bias the body in the closed position relative to the base.

5. The information handling system of claim 1, wherein the body comprises an alignment feature extending therefrom and configured to align the body relative to at least one of the information handling resource and another adjacent information handling resource.

6. The information handling system of claim 5, wherein the at least one alignment feature is further configured to minimize mechanical shock and vibration of the body.

7. The information handling system of claim 1, wherein the information handling resource comprises a memory module.

8. An insert assembly configured to mechanically couple to a circuit board of an information handling resource, the insert assembly comprising:
a base configured to mechanically attach via a press-fit mechanical coupling to an edge of the circuit board; and
a body mechanically coupled to the base.

9. The insert assembly of claim 8, wherein the base comprises at least one tensioning feature configured to have mechanical tension relative to the remainder of the base such that when the base is mechanically attached to the circuit board, the at least one tensioning feature is configured to apply a mechanical force to the circuit board to mechanically retain the base to the circuit board.

10. The insert assembly of claim 8, wherein the body is rotatably coupled to the base and configured to rotate relative to the base between an open position and a closed position.

11. The insert assembly of claim 10, wherein the base comprises at least one mechanical feature configured to mechanically engage with a corresponding mechanical feature of the body in order to bias the body in the open position relative to the base and/or bias the body in the closed position relative to the base.

12. The insert assembly of claim 8, wherein the body comprises an alignment feature extending therefrom and configured to align the body relative to at least one of the information handling resource and another adjacent information handling resource.

13. The insert assembly of claim 12, wherein the at least one alignment feature is further configured to minimize mechanical shock and vibration of the body.

14. The insert assembly of claim 8, wherein the information handling resource comprises a memory module.

15. A method for constructing an insert assembly configured to mechanically couple to a circuit board of an information handling resource, the method comprising:
mechanically coupling a body to a base such that the base, wherein the base is configured to mechanically attach via a press-fit mechanical coupling to an edge of the circuit board.

16. The method of claim 15, further comprising forming at least one tensioning feature in the base, the at least one tensioning feature configured to have mechanical tension relative to the remainder of the base such that when the base is mechanically attached to the circuit board, the at least one tensioning feature configured to apply a mechanical force to the circuit board to mechanically retain the base to the circuit board.

17. The method of claim 15, further comprising rotatably coupling the body to the base such that the base is configured to rotate relative to the base between an open position and a closed position.

18. The method of claim 17, further comprising forming at least one mechanical feature in the base, the at least one mechanical feature configured to mechanically engage with a corresponding mechanical feature of the body in order to bias the body in the open position relative to the base and/or bias the body in the closed position relative to the base.

19. The method of claim 15, further comprising forming at least one alignment feature extending from the body and configuring the at least one alignment feature to align the body relative to at least one of the information handling resource and another adjacent information handling resource.

20. The method of claim 19, further comprising configuring the at least one alignment feature to minimize mechanical shock and vibration of the body.

21. The method of claim 17, wherein the information handling resource comprises a memory module.
